(19) United States
(12) Patent Application Publication
(10) Pub. No.: US 2013/0299967 A1
(43) Pub. Date: Nov. 14, 2013

(54) WSP DIE HAVING REDISTRIBUTION LAYER CAPTURE PAD WITH AT LEAST ONE VOID

(71) Applicants: Jeffrey David Daniels, Murphy, TX (US); Gary Paul Morrison, Garland, TX (US)

(72) Inventors: Jeffrey David Daniels, Murphy, TX (US); Gary Paul Morrison, Garland, TX (US)

(73) Assignee: Texas Instruments Incorporated, Dallas, TX (US)

(21) Appl. No.: 13/469,020

(22) Filed: May 10, 2012

(51) Int. Cl. H01L 23/48; H01L 21/302

(52) U.S. Cl. 257/737; 438/689; 257/E23.021; 257/E21.214

(57) ABSTRACT

A MP die with a redistribution layer (“RDL”) capture pad having at least one void therein and having an RDL capture pad outer peripheral edge and an under bump metal (“UBM”) pad positioned above the RDL capture pad and having a UBM pad outer peripheral edge positioned laterally inwardly of the RDL capture pad outer peripheral edge and positioned laterally outwardly of all the voids in the RDL capture pad.

### BACKGROUND

Integrated circuits, also referred to as “IC's” or “semiconductor chips” or simply “chips,” are electronic circuits made by diffusion of trace elements into the surface of thin substrates of semiconductor material such as silicon. Semiconductor chips are typically mass produced in the form of a single wafer that contains a large number of identical integrated circuits. The wafer is cut (“singulated”) into a number of individual semiconductor chips referred to as “dies” or “dice.”

Dies are usually “packaged” to prevent damage to the dies and to facilitate attachment of the dies to circuit boards. Various packaging materials and processes have been used to package integrated circuit dies. One conventional packaging method involves mounting individual dies in a predetermined pattern on a substrate strip. The dies mounted on the substrate strip are then covered with a protective encapsulating material. The encapsulated dies are next singulated into individual integrated circuit packages by cutting the encapsulated die/substrate strip in accordance with the predetermined die mounting pattern. Typical cutting tools include saws and punches. Each integrated circuit package generally includes at least one die and the underlying portion of the substrate strip on which it was mounted, as well as encapsulating material which typically covers the die. The underlying substrate strip is sometimes a lead frame to which the die is electrically connected and which, in turn, is adapted to be connected to a printed circuit board (“PC” board).

Over the years, integrated circuits and the circuit boards to which they are attached have become physically smaller and more complex. One relatively new technology is known alternately as “wafer scale packaging,” “wafer level chip scale packaging,” “wafer level chip size packaging,” or other similar names. The phrase “wafer scale packaging” (“WSP”) will be used herein. Using WSP packaging, unpackaged dies, i.e., dies with no surrounding layer of protective encapsulation, may be directly mounted on printed circuit boards. The structure needed for electrical connection of dies to a printed circuit board is usually fabricated on a first surface of the dies while the dies are still integrally connected together in a single wafer. For example, in one form of WSP packaging, various layers including electrical contact pads, solder bumps and intermediate layers are formed on a first surface of dies at the wafer level. WSP eliminates conventional packaging steps such as die bonding, wire bonding, and die level flip chip attach processes to a package substrate by using the IC die itself as the electrical connection substrate. Use of the die itself as the WSP substrate significantly reduces the footprint to the IC die as compared to the same IC die attached to a package substrate.

WSP can be embodied as direct-bump WSP or redistribution layer (“RDL”) WSP which unlike direct-bump WSP adds an RDL that functions as a rewiring layer that enables repositioning external terminals at desired positions. (A redistribution layer is sometimes referred to in the art as a “redirect layer.”)

In a typical RDL WSP production flow, during back end of the line (BEOL) wafer fab processing, the IC die is provided with die pads (also known as bond pads or die bond pads) and a passivation layer. A first WSP dielectric (e.g., a polyimide) is deposited next. Lithography/etching is used to form first vias in the first WSP dielectric over the die pads, followed by deposition and patterning of an RDL including a plurality of RDL traces which contact the die pads and extend laterally therefrom. A second WSP dielectric (e.g., a polyimide) is then deposited and second vias are formed that reach the RDL in RDL capture pad positions that are laterally offset relative to the position of the die pads. Under bump metallization (UBM) pads commonly referred to as “ball pads” or “bump pads” are formed over the second vias and are coupled to and generally enclosed by RDL capture pads, followed by forming metal (e.g., solder) balls, pillars or other bonding connectors on the UBM pads. The area of the RDL capture pads is generally larger than the area of the UBM pads to absorb stresses and thus improve structural reliability. The WSP wafer is singulated to form a plurality of singulated WSP die, commonly for use on boards for portable devices where the board area is precious.

### BRIEF DESCRIPTION OF THE DRAWINGS

FIG. 1 is a cross sectional view of a WSP die having an under bump metal (“UBM”) pad which overhangs a redistribution layer (“RDL”) capture pad;

FIG. 2 is a cross sectional elevation view of a WSP die having an RDL capture pad with voids therein;

FIG. 3 is a top plan view of some layers of the WSP die of FIG. 1, showing the relative position of the RDL capture pad and the UBM pad positioned above it;

FIG. 4 is a top plan view of the RDL capture pad of FIG. 2, with the outer periphery of the UBM pad shown in dashed lines;

FIG. 5 is a cross sectional view of the WSP die of FIG. 2, showing propagation of a crack through a second dielectric layer; and

FIG. 6 is a flow chart of a method of making a WSP die.

### DETAILED DESCRIPTION

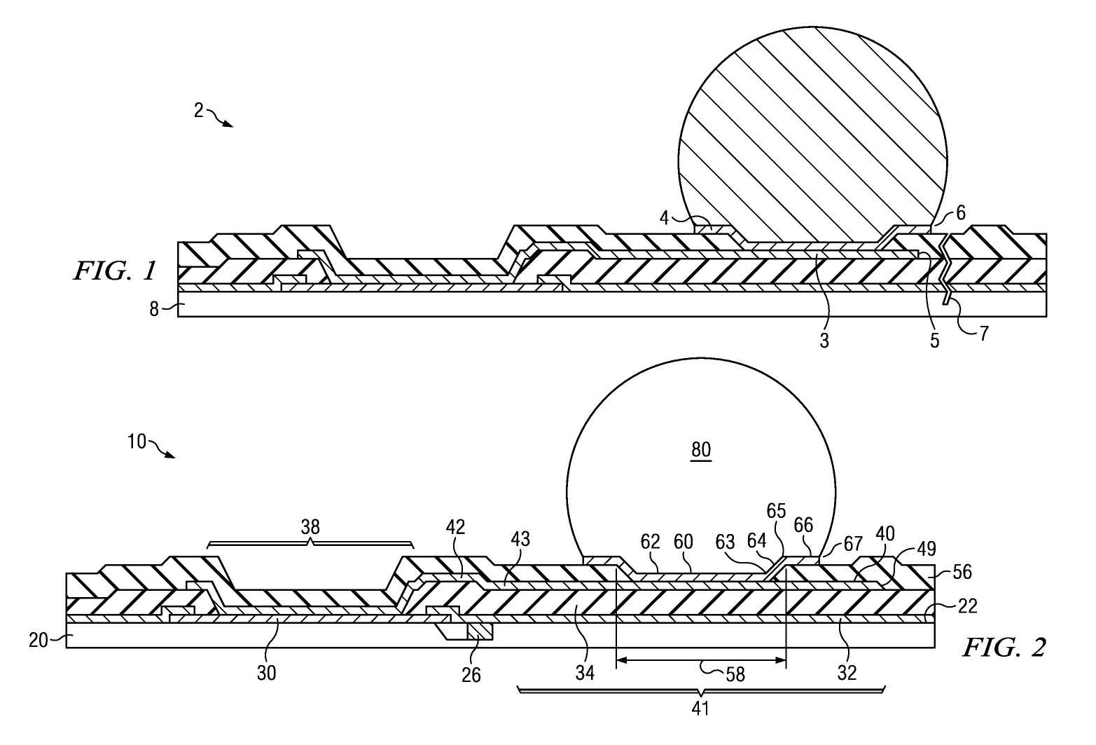

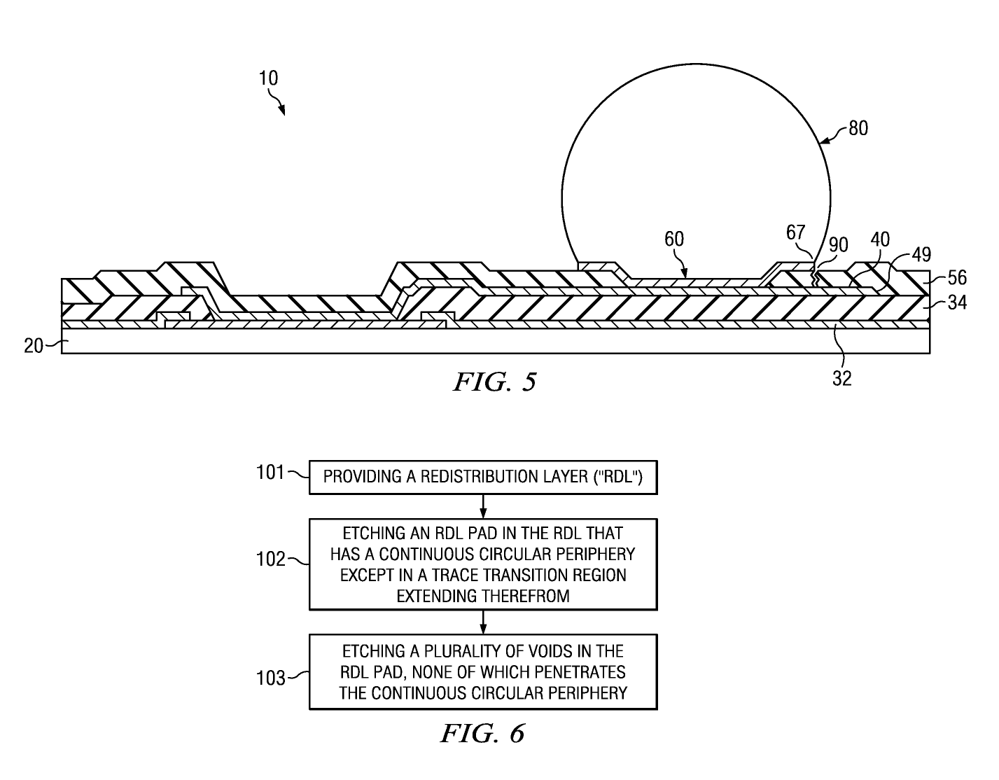

This Description discloses a wafer scale package (“WSP”) die 10 and a method of making a WSP die 10. The WSP die 10 may include, as shown in FIGS. 2-5, a redistribution layer (“RDL”) capture pad 41 having at least one void 47, FIG. 4, therein, and an RDL capture pad outer peripheral edge 49. The die 10 may also include an under bump metal (“UBM”) pad 60 positioned above the RDL capture pad 41. The UBM pad 60 may have a UBM pad outer peripheral edge 67 positioned laterally inwardly of the RDL capture pad outer peripheral edge 49. The UBM capture pad 41 is also positioned laterally outwardly of the at least one void 47 in the RDL capture pad. One advantage of this structure is that it tends to inhibit the propagation of downwardly extending cracks 90 that may begin near the outer peripheral edge 67 of the UBM capture pad 60, as shown in FIG. 5. Another advantage is that the reduction in area of the RDL pad 41 improves RDL performance by reducing capacitive parasitic effects. One method of making a WSP die 10 that is disclosed herein includes the method illustrated in FIG. 6. The method, as indicated at 101, may include providing a WSP die 10 with an RDL 40. The method may also include etching in the RDL 40 an RDL pad 41 that has a continuous circular periphery 49, as shown at 102. The method may further include, as shown at 103, etching a plurality of voids 47 in the RDL pad 40, in such a way that none of the voids 47 penetrate the continuous circular periphery 49. Having thus described a WSP die 10 and a method of producing it in general terms, the die 10 and methodology will now be described in further detail.

WSP dies (also referred to as WSP “chips”) are often connected to external circuitry, e.g. printed circuit (“PC”) boards, wiring substrates or other chips, using ball grid arrays, formed on a front (top) face of each die, which is placed in electrical contact with corresponding connectors on the external circuitry. WSP dies that have such ball grid arrays are sometimes referred to in the art as “flip chips” because the ball grid array is simply “flipped over” to a front (top) face down orientation to connect it to the external circuitry. In designing WSP dies with ball grid arrays there are conflicting considerations. The size of each ball, and thus the diameter of the under bump metal (UBM) layer to which the ball is attached, cannot be reduced because of mechanical reliability considerations. However, large balls are generally undesirable for balls that transmit RF signals because the associated large UBM layer and corresponding large redistribution layer (RDL) capture pad to which the UBM is attached create capacitance related parasitic effects. These parasitic effects manifest themselves in lower transmission power, poorer signal matching, and/or lower band width of operation, etc. for a typical wireless transceiver. In typical WSP dies the RDL capture pad has a larger footprint than the UBM pad. Reducing the size of the RDL capture pad would reduce the capacitance/parasitic effects. However, reducing the size of the RDL capture pad creates other problems as illustrated by FIG. 1. FIG. 1 is a cross sectional elevation view of a portion of a WSP die 2. The WSP die 2 has a RDL capture pad 3 which terminates at an outer periphery 5. The WSP die 2 has a UBM pad 4 which is positioned above and contacts a portion of the RDL capture pad 3. The UBM pad 4 has an outer peripheral edge 6 which extends radially outwardly beyond the outer peripheral edge 5 of the RDL capture pad. FIG. 1 illustrates a problem that may occur in a die 2 with this construction. Cracks, such as crack 7, often form near the outer peripheral edge 6 of the UBM pad 4. Crack 7 may propagate downwardly, unimpeded, through various die layers below the UBM, passing outwardly of the RDL peripheral edge 5, and ultimately entering silicon substrate 8. The crack 7 may thus damage transistors and/or other electronics in the silicon substrate 8 as well as other layers of the die 2. Applicants have designed a WSP die with a relatively smaller area RDL capture pad, in which the above described cracking problem is considerably reduced, and in which RF transmission may be improved due to lower capacitance of the smaller RDL capture pad area.

In describing the various features of a WSP die, applicants have used terms of positional/directional reference such as “up,” “down,” “bottom”, “top,” “above,” “below,” “lateral” and “vertical” which are sometimes used in reference to an orientation with respect to the surface of the earth. Such terms are not used in that sense in this application. Rather, terms such as up, down, etc. are used in a relative sense to indicate the position of a die layer or surface, etc. with respect to other layers or surfaces, etc. in a structure which initially is oriented as shown in the drawings. As used in this sense the “top” of a car would still be referred to as the “top” of the car, even when the car is subsequently positioned upside down in a ditch. Also, it will be understood by those skilled in the art that, for the most part, various layers of a die are arranged in parallel planes that are separated vertically, i.e., in a direction perpendicular to the planes, by very small distances, e.g. 0.1-10 μm. When a first layer is positioned over a second layer in this manner, a portion of the first layer, which projects laterally outwardly from a vertical projection of the second layer that is superimposed onto the first layer, will simply be referred to as projecting laterally outwardly from the second layer and vice verse, even though the two layers are positioned in different planes.

A WSP die 10 having an RDL capture pad 41 with an outer peripheral edge 49 extending laterally farther than the outer peripheral edge 67 of a UBM pad 60 is illustrated in FIGS. 2-5. The RDL capture pad 41 has at least one void 47 in a region thereof positioned beneath the UBM pad 60. The at least one void 47 in the RDL capture pad 41 reduces capacitive parasitic effects and thus improves RF signal performance of the die as compared to a die of identical construction except without at least one void 47 in the RDL capture pad 41.

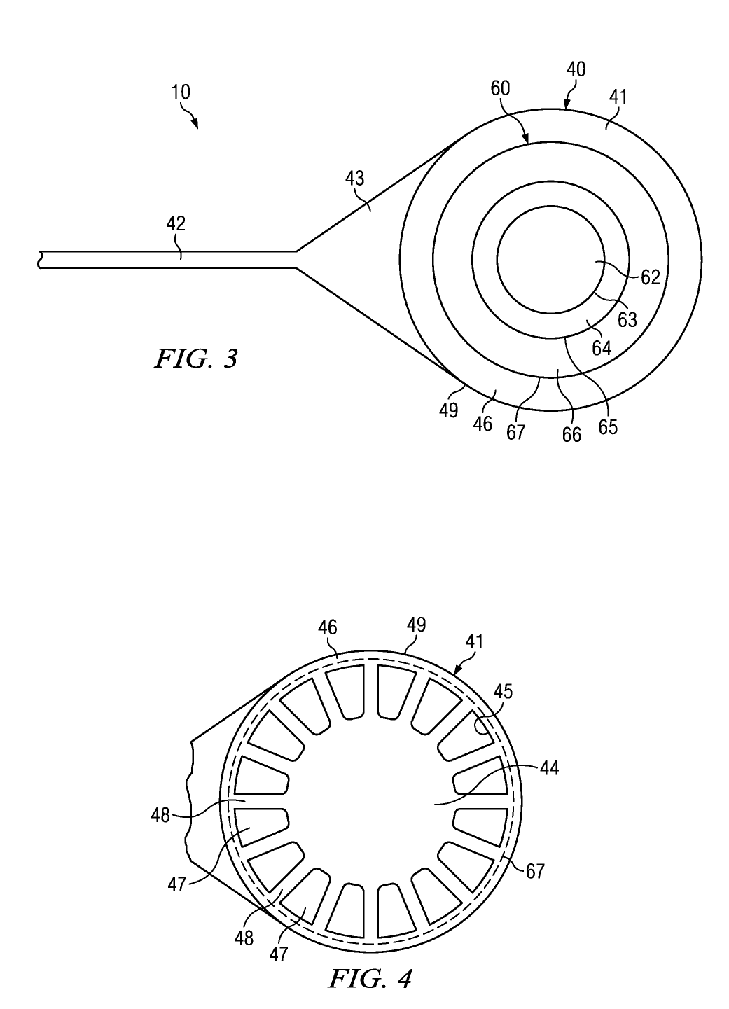

FIG. 2 illustrates a WSP die 10 that has a semiconductor substrate 20, which may be a silicon substrate. The substrate 20 has an upper surface 22 and internal circuitry 26. A metal die pad 30 is formed on the substrate upper surface 22. The metal die pad 30 may be made from, for example, Copper (Cu) or Aluminum (Al). A passivation layer 32 is also formed on the substrate upper surface 22. The passivation layer 32 extends laterally from the metal die pad 30. In the illustrative embodiment, a small portion of the passivation layer 32 extends up and over a peripheral edge portion of the die pad 30. The passivation layer 32 may be made from, for example, Silicon Nitride (SiN) or Silicon Oxynitride (SiON). A first dielectric layer 34, which may be a polyimide layer, is positioned over the metal die pad 30 and passivation layer 32. A first via is formed through the first passivation layer in a truncated cone shaped via, indicated at 38, so as to expose the metal die pad 30 through the first dielectric layer 34. A redistribution layer (RDL) 40 is applied on top the first dielectric layer 34 and may be generally “tadpole” shaped, having a circular RDL capture pad 41 and a narrow, laterally extending RDL lead 42 connected to the RDL capture pad 41 in an RDL transition region 43. The RDL lead 42 extends into contact with the upper surface of metal die pad 30, thus electrically connecting the metal die pad 30 with the RDL capture pad 41. The general shape of the RDL 40, as viewed from the top, is best illustrated in FIG. 3. The RDL 40 may be made from, for example, Copper (Cu). Returning to FIG. 2, a second dielectric layer 56, which may also be a polyimide layer, is formed on top of the RDL 40 and also on top of a portion of the first dielectric layer 34, which extends beyond the RDL 40. A generally truncated cone shaped via is extended through the second dielectric layer 56 at a lateral position illustrated at 58. The via extends through the second dielectric layer 56 to the RDL layer capture pad 41.

Referring still to FIG. 2, an under bump metal (“UBM”) pad 60 is formed on top of the exposed area of the RDL capture pad 41 and an annular portion of the second dielectric layer 56. The UBM pad 60 thus includes a circular, radially extending central portion 62 and annular sloped portion 64 connected to central portion 62 at transitional line 63. The UBM pad 60 further includes an annular, radially extending portion 66 which terminates at an outer peripheral edge 67. An annular connection line 65 is where slope portion 64 and radially extending portion 66 meet. The UBM may be made from, for example, Copper (Cu). A solder ball 80 or other connector may be attached to the UBM pad 60.

A top view of the UBM pad 60 and its relative position with respect to RDL 40 is illustrated in FIG. 3. FIG. 4 is another top view showing details of one embodiment of RDL capture pad 41 and the relative position of the UBM outer peripheral edge 67, which is illustrated with a dotted line. As best shown by FIG. 4, the RDL capture pad 41 has an inner circular portion 45 and an annular outer portion 46 with an outer peripheral edge 49. The inner circular portion 45 includes at least one void 47, which in FIG. 4 comprises a plurality of voids 47. In this embodiment the voids 47 terminate at the border between the inner circular portion 45 and the outer annular portion 46. In the embodiment of FIG. 4, the voids 47 are identically shaped and symmetrically arranged around a solid central portion 44. Thus the RDL capture pad 41 has a generally wagon wheel shaped configuration with solid areas between the voids 47 defining radially extending spokes 48. The annular outer portion 46 terminates at an outer peripheral edge 49 which in the embodiment of FIG. 4 is a circular peripheral edge 49. Also, as shown by FIG. 4, the outer peripheral edge 67 of the UBM pad overlaps, i.e., extends radially beyond, the inner circular portion 45 of the RDL capture pad. As a result of the voids 47, the total solid area of the RDL capture pad 41 is considerably smaller than the total area defined by circular peripheral edge 49. In one embodiment, the total solid area of the RDL capture pad 41 is substantially smaller than the circular area defined by UBM pad outer peripheral edge 67. Thus, the parasitic capacitive effects produced by an RDL capture pad 41 and UBM pad 60 of this configuration is considerably less than a configuration in which the RDL capture pad 41 has no such voids 47. Also, the RDL capture pad 41, because of its relatively large diameter, provides a more stable structure than that provided by a die such as shown in FIG. 1, which may have the same amount, or more, solid area but a smaller diameter. This positive effect is illustrated in FIG. 5 which shows the die 10, as illustrated in FIG. 2, in which a crack 90 has formed in the second dielectric layer 56 near the outer peripheral edge 67 of the UBM pad 60. Because of the greater lateral extension of the RDL capture pad 41, a crack 90 beginning in the second dielectric layer 56 propagates only as far as the RDL capture pad 41 before it is halted by the RDL capture pad. In the embodiment of FIG. 1 in which the UBM pad 60 overhangs the peripheral edge 5 of the RDL capture pad 3, there is no RDL portion present to stop the propagation of crack 7, which propagates downwardly into the silicon substrate 8. Also, since the redistribution layer 40 is etched to form the RDL capture pad 41 and RDL lead 42, the formation of voids 47 in the RDL capture pad 41 can be accomplished at the same time the capture pad 41 itself and the RDL lead 42 are formed. Thus, there is no additional cost associated with forming the RDL 40 in this manner. Although, in the illustrated embodiment, the RDL capture pad 41 and UBM pad 60 both have a circular outer periphery, in other embodiments the structures may have polygonal, oval or other bilaterally symmetrical geometric shapes so long as the portion of the RDL capture pad 41 positioned below the UBM pad 60 has a reduced area provided by voids.

In one embodiment the area of the RDL capture pad 41, excluding the area of the voids, is at least 20% less than the area defined by the outer peripheral edge 67 of the UBM 60. In another embodiment the diameter of the RDL pad 41 outer peripheral edge 49 is at least 10% greater than the diameter of the UBM pad 60 outer peripheral edge 67.

Although certain embodiments of a WSP die have been described in herein, many alternative embodiments will be apparent to those skilled in the art after reading this disclosure. It is intended that the appended claims be construed to encompass all such alternative embodiments, except to the extent limited by the prior art.

What is claimed is:

1. A WSP die comprising:
a redistribution layer (“RDL”) capture pad having at least one void therein and having an RDL outer peripheral edge; and
an under bump metal (“UBM”) pad positioned above said RDL capture pad and having a UBM pad outer peripheral edge positioned laterally inwardly of said RDL capture pad outer peripheral edge and positioned laterally outwardly of said at least one void in said RDL capture pad.

2. The WSP die of claim 1 wherein said at least one void comprises a plurality of voids.

3. The WSP die of claim 1 wherein said RDL outer peripheral edge comprises a bilaterally symmetrical geometric shape.

4. The WSP die of claim 1 wherein said RDL outer peripheral edge comprises a circle shape.

5. The WSP die of claim 2 wherein said plurality of voids are the same shape.

6. The WSP die of claim 5 wherein said plurality of voids are evenly spaced circumferentially.

7. The WSP die of claim 5 wherein said plurality of voids are all positioned at an identical radial distance from a center point of said RDL capture pad.

8. The WSP die of claim 1 wherein said RDL capture pad comprises a wagon wheel shape.

9. The WSP die of claim 1 wherein said RDL capture pad has a total open area occupied by said at least one void and a total remaining area that is not occupied by said at least one void and wherein said outer peripheral edge of said UBM defines a UBM area and wherein said total remaining area of said RDL capture pad is less than said UBM area.

10. A method of making a WSP die comprising:
providing a redistribution layer (“RDL”);
etching in the RDL an RDL pad that has a circular periphery; and
etching a plurality of voids in said RDL pad, none of which penetrates said circular periphery.

11. The method of claim 10 further comprising etching an under bump metal (“UBM”) pad directly above said RDL pad that has a circular outer periphery having a diameter smaller than a diameter of said circular periphery of said RDL pad.

12. The method of claim 11 wherein said plurality of voids in said RDL are all etched radially inwardly of said circular outer periphery of said UBM pad.

13. The method of claim 11 wherein said etching an RDL pad and said etching a plurality of voids in said RDL pad comprise etching a wagon wheel shaped RDL pad.

14. A WSP die comprising:
a semiconductor substrate;
a metal die pad attached to said semiconductor substrate;
a passivation layer attached to said semiconductor substrate and to said metal die pad;
a first dielectric layer attached to said passivation layer and to said metal die pad;
a redistribution layer (“RDL”) attached to said first dielectric layer and to said die pad and comprising an RDL capture pad having an outer circular periphery with an RDL capture pad outer diameter and having a plurality of voids therein;
a second dielectric layer attached to said redistribution layer and to said first passivation layer; and
an under bump metal layer (“UBM”) pad attached to said redistribution layer and to said second dielectric layer and having an outer circular periphery with a UBM pad outer diameter which is smaller than said RDL capture pad outer diameter, wherein said UBM outer periphery is positioned radially outwardly of said plurality of voids in said RDL capture pad.

15. The WSP of claim 14 wherein said voids are distributed symmetrically in said RDL capture pad.

16. The WSP of claim 15 wherein said voids define a plurality of radially extending spokes.

17. The WSP of claim 16 wherein said radially extending spokes terminate at a radial distance from a center point of the RDL capture pad that is equal to about 90% of the RDL capture pad radius.

18. The WSP of claim 14 wherein said voids extend from a solid central hub shaped portion of said RDL capture pad to an outer rim shaped portion of said RDL capture pad, whereby said RDL capture pad comprises a generally wagon wheel shape.

19. The WSP of claim 14 wherein the area of said RDL capture pad, excluding the area of said voids, is at least 20% less than the area defined by said outer circular periphery of said UBM pad.

20. The WSP of claim 14 wherein said RDL capture pad outer diameter is at least 10% greater than said UBM pad outer diameter.
